(19) United States
(12) Patent Application Publication
(10) Pub. No.: US 2004/0007940 A1
(43) Pub. Date: Jan. 15, 2004

(54) Thin film acoustic wave device and the manufacturing method thereof

(75) Inventors: Shu-Hui Tsai, Hsin-Chu City (TW); Ching-Yee Chang, Hsinchu (TW); Chung-Hsien Lin, Cha-I City (TW)

Correspondence Address: BRUCE H. TROXELL, SUITE 1404, 5205 LEESBURG PIKE, FALLS CHURCH, VA, 22041, US

(73) Assignee: Asia Pacific Microsystems, Inc.

(21) Appl. No.: 10/194,215

(22) Filed: Jul. 15, 2002

(51) Int. Cl. H03H 9/25

(52) U.S. Cl. 310/313 R

(57) ABSTRACT

A thin film acoustic wave device and the manufacturing method thereof, it provides a method of manufacturing acoustic wave devices of different FOM (figures of merit) by means of the crystalline orientation of the piezoelectric layer in cooperated with the various electric field directions of the driving electrode, so as to provide acoustic wave devices that are optimized under various specifications.

### BACKGROUND OF THE INVENTION

1. Field of the Invention

The present invention relates to a thin film acoustic wave device and the manufacturing method thereof, especially to a method to manufacture acoustic wave devices of different FOM (figures of merit) by means of the crystalline orientation of the piezoelectric layer in cooperated with the various electric field directions of the driving electrode, so as to provide acoustic wave devices that are optimized under various specifications.

2. Description of the Prior Art

The mobile communication is so vigorously developed that speed up the requirement of the RF (radio frequency) wireless electronic device. The mobile ability of the wireless communication product is dependant on the size of device and the lifetime of battery. Also the devices manufacturers are dedicated to develop the tiny, cheaper and the more well performance devices. The finally step to microminiaturize the device is to integrate it with IC to form a system on chip (SOC). Presently, in the RF front-end of the wireless system, one of the devices that still can not be integrated with the IC, is RF front-end filter. In the future, the RF front-end filter will be the occupied space and the necessary device in the double, triple or multiple-band standards. The multiplexer obtained by associating the RF switch with RF front-end filter would be the key to decide the communication quality.

The ordinarily used RF front-end filter is the surface acoustic filter. In the past, the surface acoustic filter is not only to be the RF front-end filter but also to be the channel selective filter in the IF (intermediate-frequency) band. But in accompany with the development of the direct conversion technique (that is, the zero-IF or near zero-IF technique), it does not need more analog IF filter, so the application of the surface acoustic filter can only be extended to the RF filter. But the surface acoustic filter itself has the larger insertion loss and it has worse power dissipation stand. In the past, the insertion loss standard in the use of IF channel selective filters is not rigorous, and the IF band belongs to the RF back-end so that it is not necessary to use a well power dissipation stand. But now, if it is used in the RF front-end, the aforementioned both standards will be the problem to the surface acoustic filter.

In order to solve the problem, the Sumitomo Electric Industries, Ltd. in Japan disclosed the growing across finger electrode on the zinc oxide/diamond/silicon substrate. Due to the high spring constant and well thermal conductivity of the diamond, the inter-digital transducer on the compound substrate could stand about 35 dBm dissipation and still could maintain the good linearity. But it is rather expensive about the diamond substrate, and the line pitch of the inter-digital transducer is below micrometer. Besides, it has the lower error tolerance and expensive in the equipment investment.

The other product of RF filter is the low temperature cofired ceramics (LTCC). The low temperature cofired ceramics (LTCC) owns the best benefit of higher stand to the RF dissipation. However, it still has other problems that have to be solved, such as: the difficulty in measurement, and not easy to get the ceramic powder from the upper company, and the ceramic happened the shrinkage phenomenon in the manufacturing processes that the deviations of products were caused and it is difficult to modify.

Recently, the technique about the bulk acoustic wave filter device, such as the film bulk acoustic resonator (FBAR) device (refer to the U.S. Pat. No. 6,060,818) developed by HP company, and the stack bulk acoustic resonator (SBAR) device (refer to the U.S. Pat. No. 5,872,493) provided by Nokia company, which could diminish the volume of the high efficiency filter product, and it could operate in 400 MHz to 10 GHz frequency band. The diplexer using in the CDMA mobile phone is one kind of said filter product. The size of the bulk acoustic wave filter is just a part to the ceramic diplexer, and it owns better rejection, insertion loss, and power management ability than the surface acoustic filter. The combination of those properties could make the manufacturer produce high performance, up-to-date, and mini-type wireless mobile communication equipment. The bulk acoustic wave filter is a semiconductor technique, so it could integrate the filter into the RFIC, and to form the system on chip (SOC).

In SBAR device, although the vacant construction is not necessary to be formed below the resonator, a multi-layer film is necessary to be grown. Such processes are rather complicated and not advantageous to integration. The selection of the materials for the Bragg reflection layer is restricted, so the device yield is relative low, but it still has an advantage of multiple selectivity of the substrate.

It is necessary to form a vacant construction below the resonator in the FBAR device. In general, a developed way is to fabricate the vacant construction by backside etching or front-side etching the substrate. As the backside etching is being proceeded, the density of the devices thereof is restricted greatly. As shown in FIG. 1, a supporting layer 14, a lower electrode pattern 12′, a piezoelectric material layer 13, and an upper electrode metal pattern 12 are formed sequentially. Thereafter, backside etching is proceeded to form a cavity 10 in the desired resonator region. It needs more time for backside etching since the etching depth of backside etching is relatively deep; and it also needs quite a long time for front-side etching since the side etching is performed from the side of non-crystalline to excavate the substrate below the resonator. As shown in FIG. 2, a supporting layer 24, a lower electrode pattern 22′, a piezoelectric material layer 23, and an upper electrode metal pattern 22 are formed sequentially onto the substrate 21. Thereafter, front-side etching is proceeded to form a cavity 20 on the desired resonator region, and the silicon substrate residue 28 is remained.

FIG. 3 is a cross-sectional view showing the bulk acoustic wave filter proceeded with front-side etching by using a sacrificial layer according to the U.S. Pat. No. 6,060,818 of the HP company. As shown in FIG. 3, the bulk acoustic wave filter device can be formed on a substrate 31. First, a cavity 30 is mask defined and etched on the substrate. Then a sacrificial layer 35 is deposited onto this region. Then the sacrificial layer 35 is performed with polishing process by using the methods of chemical-mechanical polishing. Afterwards, the supporting layers 34, the lower electrode patterns 32′, the piezoelectrical material layers 33, and the upper electrode metal patterns 32 are formed sequentially onto the construction. Then, front etching is being performed on the desired resonator region to remove the sacrifice layer 35, and a cavity 30 is formed, so that the device properties would not be influenced by the substrate. There are disadvantages that the sacrificial layer 35 should have a specified thickness in order to form a cavity deep enough for avoiding the influence of the substrate. And the smoothening process, such as being pre-grooved on the substrate and the chemical-mechanical polishing process to the sacrifice layer, is necessary for proceeding the manufacturing process.

However, the quality and the efficiency of a normal acoustic wave device are decided by the quality and the steadiness of the etched cavity, and they are further depended on the FOM (figure of merit) of the device, which is defined as K²Q (wherein, K² indicates the piezoelectric coupling constant, Q indicates the quality factor of the device). For the more various applications in the future, various values of the piezoelectric coupling constant K² should be provided for accommodating the specifications of the devices. The commercially used surface acoustic wave devices with various piezoelectric substrates and the application fields thereof are described as below. [Reference Materials: C. K. Campbell Surface Acoustic Wave Devices for Mobile and Wireless Communications, page 31]

TABLE 1

| | | Trans- | | | | |
|---|---|---|---|---|---|---|
| | Tangential | mission | | | | |
| | Direction | Axis | | | | |
| | of the | of the | Acoustical | | Tempera- | |
| | Crystal | Acoustic | Velocity | K² | ture | Main |
| Material | Surface | Wave | (m/sec) | (%) | Coefficient | Purpose |
| Quartz | ST | X | 3158 | 0.11 | ˜0 | accurate oscillator, |
| | | | | | (near 25° C.) | constant-temperature |
| | | | | | | narrow-band LF filter |
| | | | | | | low-loss LF resonator |
| LiNbO₃ | Y | Z | 3488 | 4.5 | 94 | broadband LF filter |
| LiNbO₃ | 128° | X | 3992 | 5.3 | 75 | broadband LF filter |
| Bi₁₂GeO₂₀ | 110 | 001 | 1681 | 1.4 | 120 | delay line |
| LiTaO₃ | 77.1° | Z’ | 3254 | 0.72 | 35 | low-loss oscillator |
| | Rotated Y | | | | | |
| GaAs | (100) | (110) | <2841 | <0.06 | 35 | processes for |
| | | | | | | manufacturing the filters |
| | | | | | | corresponding with the |
| | | | | | | semiconductors |

It is known from above that a piezoelectric material with a less value of K², such as a quartz substrate, is applied for the accurate oscillators and resonators, or for the frequency-selection of the LF filters. And, a piezoelectric material with a larger value of K², such as a LiTaO₃ substrate or a LiNbO₃ substrate, is applied for the broadband applications. For the thin film bulk acoustic wave substrate in the future, the quartz substrate, the LiTaO₃ substrate or the LiNbO₃ substrate can not be integrated into the silicon substrate or the gallium arsenide (GaAs) substrate. There are two kinds of piezoelectric films that are commonly used—the zinc oxide (ZnO) film and the aluminum nitride (AIN) film. Wherein, the ZnO film is normally used on a GaAs substrate, both have approximate acoustical velocities. If an interlayer, such as a silicon nitride (SiₓN_{y}) layer or a silicon oxide nitride (SiOₓN_{y}) layer, is applied between the ZnO film and the GaAs substrate for increasing the adhesion of the ZnO film to the GaAs substrate, the coupling efficiency of the acoustic wave can be raised apparently, and the acoustical velocity can be corrected accordingly. However, the quality of the thin film acoustic wave device would be lowered because of the acoustic wave loss of SiₓN_{y} or SiOₓN_{y}, and it is very disadvantageous to the manufacturing processes of the acoustic wave devices.

FIGS. 4a and 4b are the illustrations of a prior technique of the U.S. Pat. No. 04,640,756 by the Department of Energy Resources of America, wherein a film-growing method for growing a piezoelectric film with specific crystalline direction is used for accomplishing a best value of K² for the devices. In this prior technique, the direction of the driving electrode for driving the piezoelectric film is fixed to a direction towards the thickness of the film. In the manufacturing process of the film, the inclined direction of the C-axis of the lattice is adjusted in order to obtain various values of K², and a best quality and reasonable specifications are accomplished. As shown in FIG. 4a, wherein the numeral 40 indicates the direction for forming the film, 41 indicates the inclined direction of the C-axis of the film lattice, 43 indicates the upper electrode, 44 indicates the piezoelectric film layer, and 45 indicates the lower electrode. A cross axle in FIG. 4b is exhibited by the included angle between the inclined direction 41 of the C-axis of the film lattice and the film-growing direction 40. FIG. 4b shows an example of a ZnO piezoelectric film, wherein the value of K² of film would be changed according to the inclined direction 41 of the C-axis of the lattice. Moreover, a maximum value of K² is happened when the C-axis has an inclination angle of about 36 degrees. However, the growth of the piezoelectric film towards lattice direction is not similar to the piezoelectric crystal, of which the inclined direction of the crystal axis with regard to the driving electrode is controlled by the back-end cutting and grinding processes. Therefore, in the prior techniques, it is impossible to obtain various values of the piezoelectric coupling constant K², which depend on the direction control of the crystal axis of the piezoelectric crystal, for accommodating the devices with various specifications.

### SUMMARY OF THE INVENTION

Accordingly, the present invention is provided for solving the disadvantages of the prior technology as described above.

It is an object of the present invention to provide a thin film acoustic wave device and the manufacturing method thereof, thus the acoustic wave devices with various FOM (figure of merit) can be manufactured.

Another object of the present invention is to provide a thin film acoustic wave device and the manufacturing method thereof, which can integrate the bulk acoustic wave device and the surface acoustic wave device, thus an optimized designs and manufacturing method under various specifications can be provided in order to reduce the development time of the products.

To achieve the above objects, the thin film acoustic wave device and the manufacturing method thereof according to the present invention, wherein the acoustic wave devices with various FOM (figure of merit) can be manufactured by means of the crystalline orientation of the piezoelectric material in cooperate with various directions of the electric field of the driving electrodes.

To achieve the above objects, the acoustic wave device and the manufacturing method thereof according to the present invention, wherein the thin film surface acoustic wave device and the bulk acoustic wave device can be formed simultaneously; the surface acoustic wave device can be in cooperate with the bulk acoustic wave device, and they can be used as an acoustic wave device with LF specifications in the multi-frequency or multi-module wireless communication system.

The present invention will be better understood and its numerous objects and advantages will become apparent to those skilled in the art by referencing to the following drawings.

### BRIEF DESCRIPTION OF THE DRAWINGS

FIG. 1 is a perspective view showing a bulk acoustic wave filter that is proceeded with the backside etching process according to the prior technology.

FIG. 2 is a perspective view showing a bulk acoustic wave filter that is proceeded with the front-side substrate bulk etching process according to the prior technology.

FIG. 3 is a perspective view showing a bulk acoustic wave filter that is proceeded with the front-side etching process by using a sacrificial layer according to the prior technology.

FIG. 4a is a perspective view showing the film-growing method for growing piezoelectric film with specific crystalline orientation, and showing the angle between the crystalline axis and the inclined direction with regard to the driving electrode according to the prior technology.

FIG. 4b shows the relationships between the value of K² of the film-growing method in FIG. 4a for growing the piezoelectric film with specific crystalline orientation and the angle between the crystalline axis and the inclined direction with regard to the driving electrode.

FIG. 5a is a perspective view showing the first example according to the present invention, wherein the film-growing method for growing the piezoelectric film with specific crystalline orientation, and the inclination angle of the crystalline axis with regard to the driving electrode are shown.

FIG. 5b is a perspective view showing the angle between the crystalline axis and the inclined direction with regard to the driving electrode according to the film-growing method, which is shown in FIG. 5a, for growing the piezoelectric film with the crystalline orientation of the hexagonal system, such as the aluminum nitride or the zinc oxide etc.

FIG. 5c shows the relationships between the value of K² of the film-growing method, which is shown in FIG. 5a, for growing the piezoelectric film with the crystalline orientation of the aluminum nitride film, and shows the inclination angle of the crystalline axis with regard to the driving electrode.

FIG. 5d shows the relationships between the value of K² of the film-growing method, which is shown in FIG. 5a, for growing the piezoelectric film with the crystalline orientation of the zinc oxide film, and shows the inclination angle of the crystalline axis with regard to the driving electrode.

FIG. 6a is a perspective view showing the second example according to the present invention, wherein the film-growing method for growing the piezoelectric film with specific crystalline orientation, and the inclination angle of the crystalline axis with regard to the driving electrode are shown.

FIG. 6b is a perspective view showing the angle between the crystalline axis and the inclined direction with regard to the driving electrode according to the film-growing method, which is shown in FIG. 6a, for growing the piezoelectric film with the crystalline orientation of the hexagonal system, such as the aluminum nitride or the zinc oxide, etc.

FIG. 6c shows the relationships between the value of K² of the film-growing method, which is shown in FIG. 6a, for growing the piezoelectric film with the crystalline orientation of the aluminum nitride film, and shows the inclination angle of the crystalline axis with regard to the driving electrode.

FIG. 6d shows the relationships between the value of K² of the film-growing method, which is shown in FIG. 6a, for growing the piezoelectric film with the crystalline orientation of the zinc oxide film, and shows the inclination angle of the crystalline axis with regard to the driving electrode.

FIG. 7 is a perspective view showing the fourth example according to the present invention, wherein the thin film bulk acoustic wave device is integrated with the surface acoustic wave device.

### DETAILED DESCRIPTION OF THE PREFERRED EMBODIMENT

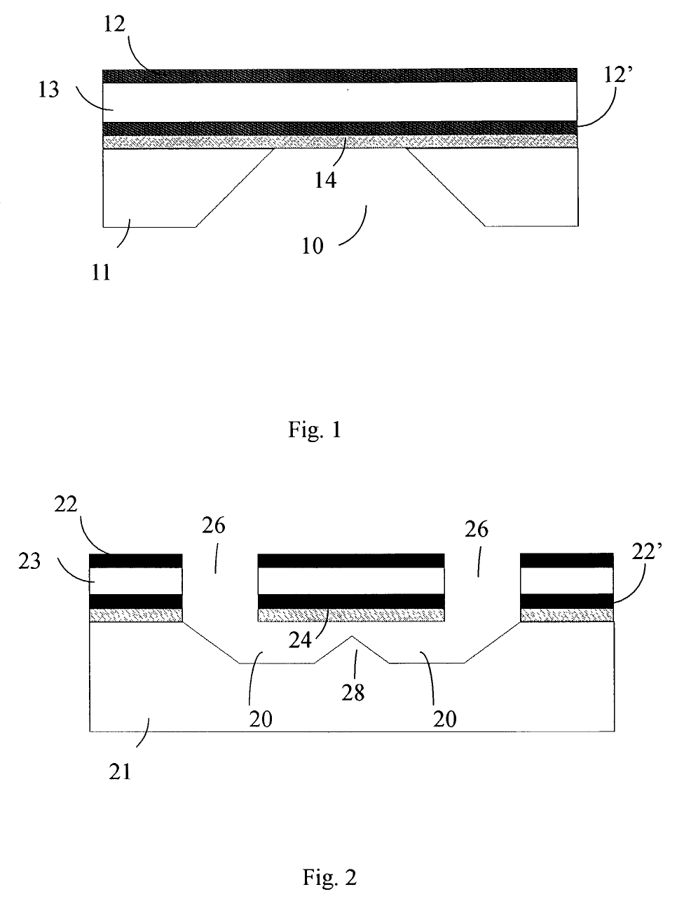

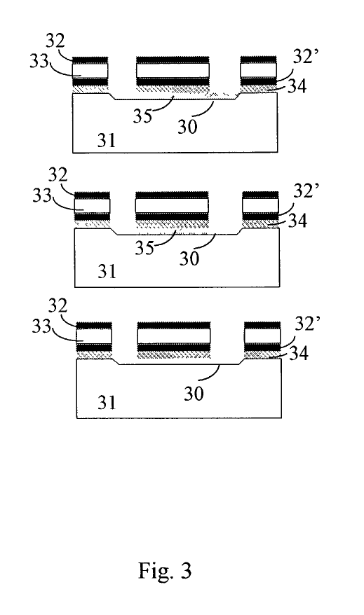

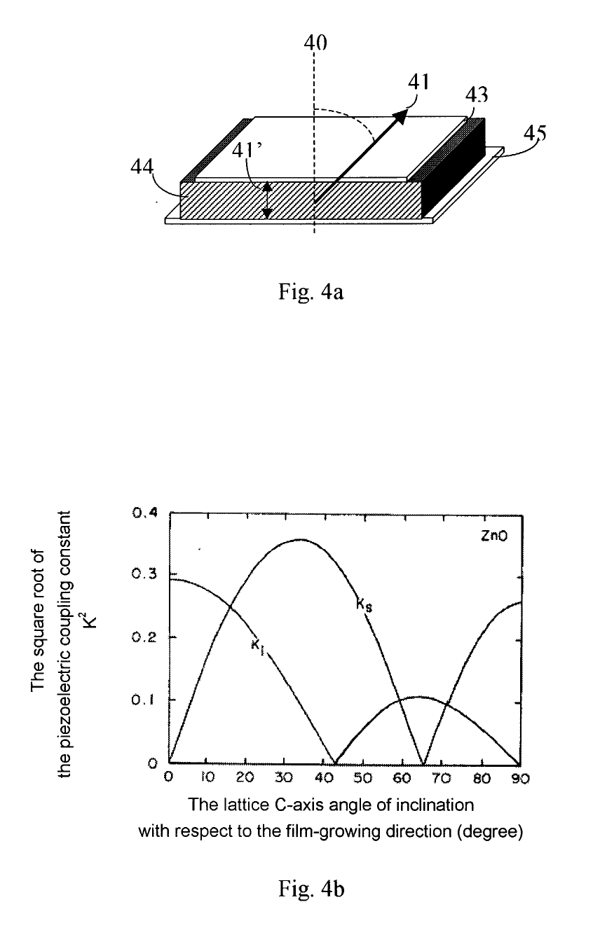

The bulk acoustic wave filter of the prior technology shown in FIG. 1 through FIG. 4 are already described as above, so it is not repeated here.

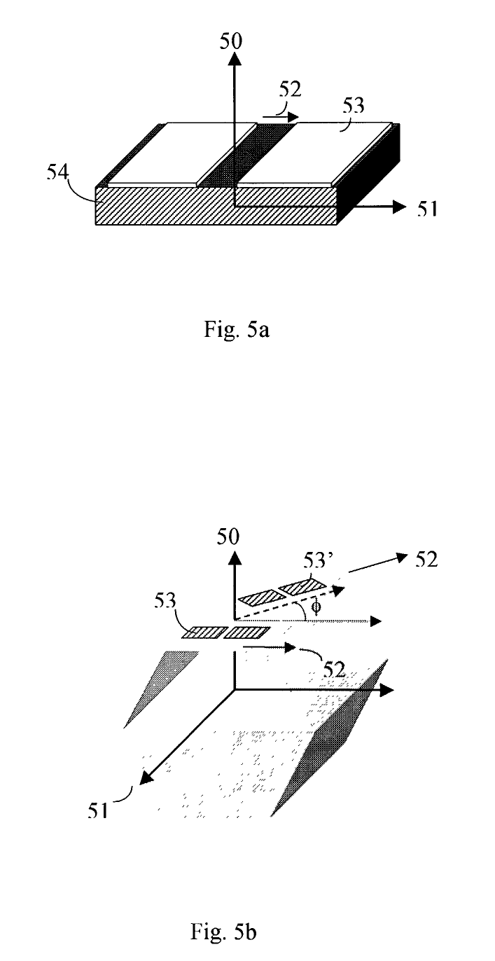

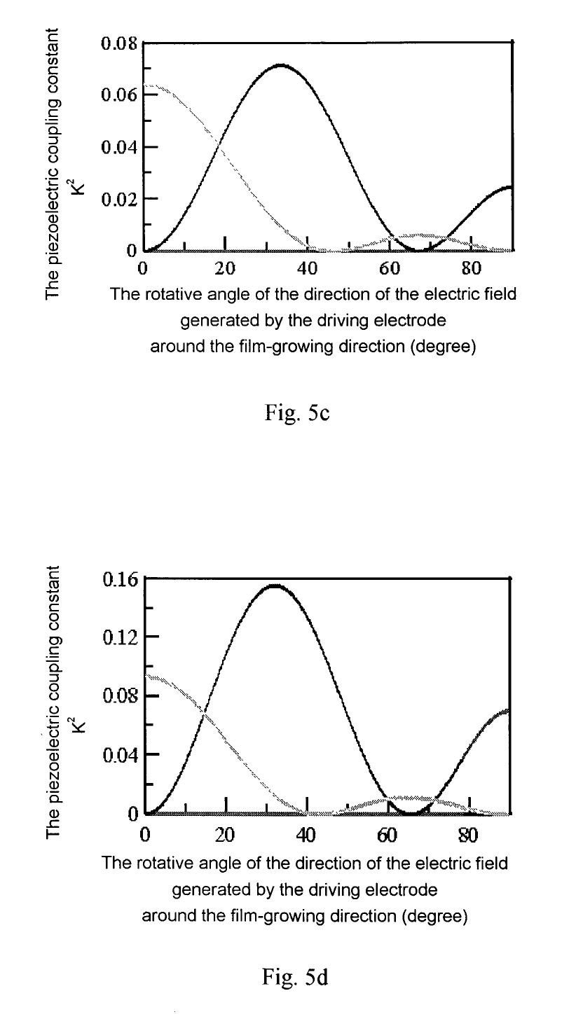

FIG. 5a is a perspective view showing the first example according to the present invention, wherein the film-growing method for growing the piezoelectric film with specific crystalline orientation, and the inclination angle of the crystalline axis with regard to the driving electrode are shown. As shown in FIG. 5a, an electric field with a direction 52 that is perpendicular to the film-thickness direction 50 is generated by the driving electrode for driving the piezoelectric film, wherein the numeral 50 indicates the direction for forming the film, 51 indicates the direction of the C-axis of the film lattice, 53 exhibits the upper electrode, 54 exhibits the piezoelectric film layer. There is an included angle of 90 degrees between the C-axis direction 51 of the film lattice and the film-growing direction 50, wherein the inclined direction of the C-axis can be measured by X-ray. At this time, the rotative angle of the electric field direction generated by driving the electrode surrounding the film-growing direction 50 is represented to the horizontal axis in FIGS. 5c and 5d.

FIG. 5c shows the relationships between the value of K² of the aluminum nitride (AIN) piezoelectric film and the rotative angle of the electric field direction generated by driving the electrode around the film-growing direction. FIG. 5d shows the relationships between the value of K² of the zinc oxide (ZnO) piezoelectric film and the rotative angle of the electric field direction generated by driving the electrode surrounding the film-growing direction. An example of an AIN piezoelectric film is shown in FIG. 5c, wherein the value of K² of the film varies with the rotative angle, and a maximum value of K² happens when the rotative angle is about 36 degrees. An example of a ZnO piezoelectric film is shown in FIG. 5d, wherein the value of K² of the film varies with the rotative angle and the variation tendency is similar to FIG. 5c, and a maximum value of K² happens when the rotative angle is about 36 degrees. Only the absolute values of K² of the two examples are different. As shown in FIGS. 5a through 5d, the electric field direction 52 generated by driving the driving electrode of the piezoelectric film is perpendicular to the film-thickness direction 50, namely, the direction of the C-axis of the piezoelectric film is perpendicular to the film-thickness growth direction 50. At this time, the value of K² of the piezoelectric film can be controlled by rotating the electric field direction 52 of the driving electrode in order to obtain an optimum quality and to correspond with the product specifications. In this example, it is unnecessary to be similar to the piezoelectric crystal, of which the inclined direction of the crystalline axis with respect to the driving electrode is controlled by the back-end cutting and grinding processes; thus the films with various values of piezoelectric coupling constant K² can be fabricated for various device specifications during the semiconductor photo-lithographic exposure process.

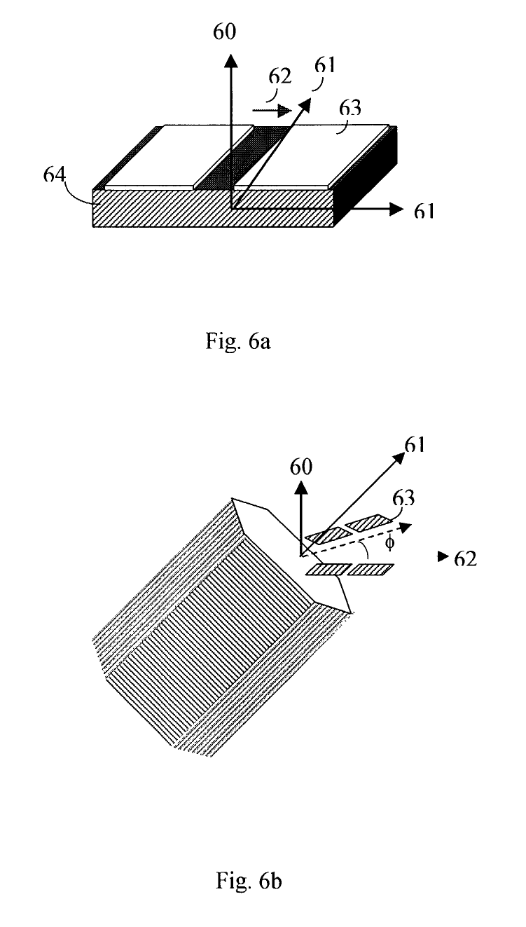

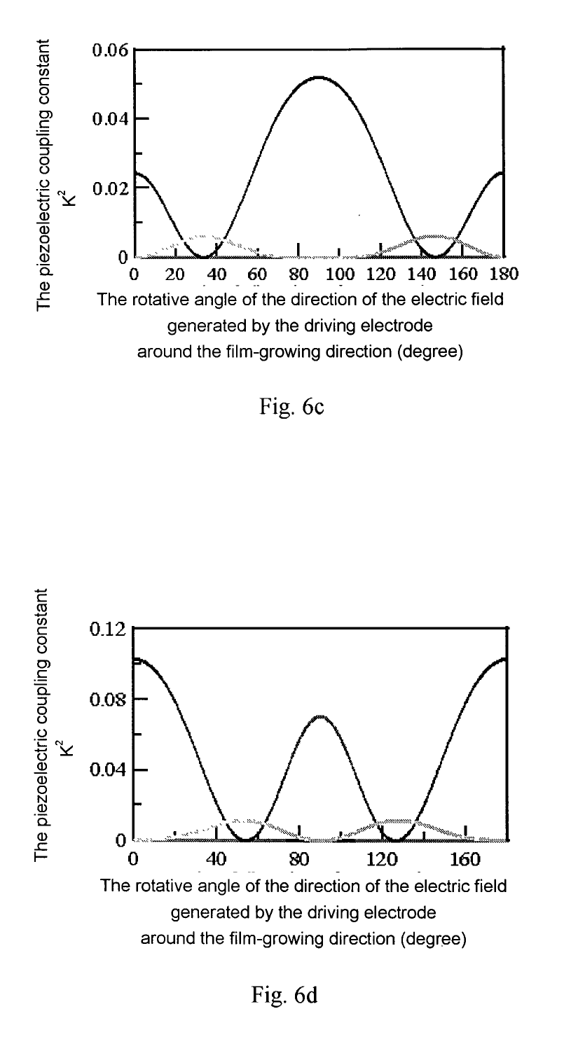

FIG. 6a is a perspective view showing the second example according to the present invention, wherein the film-growing method for growing the piezoelectric film with specific crystalline orientation, and the inclination angle of the crystalline axis with regard to the driving electrode are shown. As shown in FIG. 6a, an electric field with a direction 62 that is perpendicular to the film-thickness direction 60 is generated by the driving electrode for driving the piezoelectric film, wherein the numeral 60 indicates the direction for forming the film, 61 indicates the direction of the C-axis of the film lattice, 63 exhibits the upper electrode, 64 exhibits the piezoelectric film layer. The C-axis direction 61 of the film lattice has an inclination towards the direction [101] (namely the direction of the crystalline axis [101] when the direction of the C-axis is correspondent with the film-growing direction initially). Wherein, the inclined direction [101] can be measured by X-ray. At this time, the rotative angle of the electric field direction 62 generated by driving the electrode surrounding the film-growing direction 60 is represented to the horizontal axis in FIGS. 6c and 6d.

FIG. 6c shows the relationships between the value of K² of the aluminum nitride (AIN) piezoelectric film and the rotative angle of the electric field direction 62 generated by driving the electrode around the film-growing direction. FIG. 6d shows the relationships between the value of K² of the zinc oxide (ZnO) piezoelectric film and the rotative angle of the electric field direction 62 generated by driving the electrode surrounding the film-growing direction. An example of an AIN piezoelectric film is shown in FIG. 6c, wherein the value of K² of the film varies with the rotative angle, and a maximum value of K² happens when the rotative angle is about 90 degrees. An example of a ZnO piezoelectric film is shown in FIG. 6d, wherein the value of K² of the film varies with the rotative angle and the variation tendency is similar to FIG. 6c, and a maximum value of K² happens when the rotative angle is about 180 degrees or zero.

As shown in FIGS. 6a through 6d, the electric field direction 62 generated by driving the driving electrode of the piezoelectric film is perpendicular to the film-thickness direction, namely, the C-axis direction 61 of the piezoelectric film has an inclination towards the direction of [101]. At this time, the value of K² of the piezoelectric film can be controlled by rotating the driving electrode in order to obtain an optimum quality and to correspond with the product specifications. In this example, it is unnecessary to be similar to the piezoelectric crystal, of which the inclined direction of the crystalline axis with respect to the driving electrode is controlled by the back-end cutting and grinding processes; thus the films with various values of piezoelectric coupling constant K² can be fabricated for various device specifications during the semiconductor photo-lithographic exposure process.

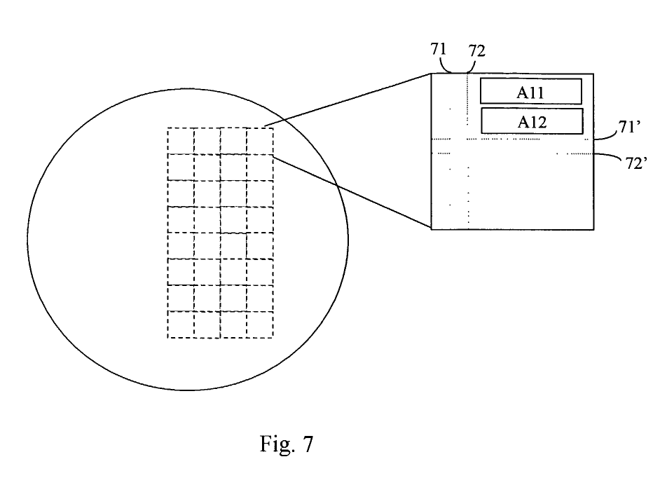

FIG. 7 is a perspective view showing the fourth example according to the present invention, wherein the thin film bulk acoustic wave device is integrated with the surface acoustic wave device. As shown in FIG. 7, wherein the numeral A11 indicates the position of the bulk acoustic wave device, and A12 indicates the position of the surface acoustic wave device. Since the multi-band specifications for the wireless communication system, such as the mobile phone is provided with dual-frequency or tri-frequency, wherein a part of the frequency band is ranged from 800 MHz to 900 MHz, so the film thickness would be over 2 μm if the thin film bulk acoustic wave device is used for fabricating the device for such range of lower frequency. Therefore, in this example, the surface acoustic wave device for the lower frequency range is positioned at A12; and the bulk acoustic wave device for the higher frequency range is positioned at A11. Thus, the thin film acoustic wave devices with various specifications can be accomplished by the same manufacturing process, an optimum design and manufacturing method for the devices with various specifications can be provided, and the development time of the products can be reduced.

Although the present invention has been described using specified embodiment, the examples are meant to be illustrative and not restrictive. It is clear that many other variations would be possible without departing from the basic approach, demonstrated in the present invention.

What is claimed is:

1. A method for manufacturing thin film acoustic wave device, characterized in that, the thin film acoustic wave device is manufactured by means of changing the angle between the wave-propagation direction and the crystalline direction of piezoelectric film using pattern-designing of the driving electrode.

2. The manufacturing method as claimed in claim 1, wherein the piezoelectric film is an aluminum nitride piezoelectric film.

3. The manufacturing method as claimed in claim 1, wherein the piezoelectric film is a zinc oxide piezoelectric film.

4. A manufacturing method for a thin film acoustic wave device, characterized in that: the C-axis of the piezoelectric film lattice has an inclination towards a specific direction; and the direction of the electric field generated by the driving electrode for driving the piezoelectric film is perpendicular to the direction of the film thickness; thus various values of the piezoelectric coupling constant K² can be obtained by changing the rotative angle of the direction of the electric field generated by the driving electrode around the film-growing direction.

5. The manufacturing method as claimed in claim 4, wherein the piezoelectric film is an aluminum nitride piezoelectric film.

6. The manufacturing method as claimed in claim 4, wherein the piezoelectric film is a zinc oxide piezoelectric film.

7. The manufacturing method as claimed in claim 4, wherein the C-axis of the piezoelectric film lattice can be inclined towards a specific direction of [101], and the inclined direction can be measured by X-ray.

8. A thin film acoustic wave device, characterized in that: it comprises a thin film bulk acoustic wave device region; and having a thin film surface acoustic wave device region.

9. The acoustic wave device as claimed in claim 8, wherein the surface acoustic wave device serves as a thin film acoustic wave device for a lower range of the frequency, and the bulk acoustic wave device serves as a thin film acoustic wave device for a high range of the frequency.
